(19) United States
(12) Patent Application Publication
(10) Pub. No.: US 2024/0005065 A1
(43) Pub. Date: Jan. 4, 2024

(54) SUPER RESOLVED SATELLITE IMAGES VIA PHYSICS CONSTRAINED NEURAL NETWORK

(71) Applicant: International Business Machines Corporation, Armonk, NY (US)

(72) Inventors: LEVENTE KLEIN, Tuckahoe, NY (US); Wang Zhou, White Plains, NY (US); Eloisa Bentivegna, Warrington (GB); Theodore G. van Kessel, Millbrook, NY (US); Bruce Gordon ELMEGREEN, Goldens Bridge, NY (US); Chulin Wang, Evanston, IL (US)

(21) Appl. No.: 17/809,562

(22) Filed: Jun. 29, 2022

(51) Int. Cl. G06F 30/27; G06V 10/44

(52) U.S. Cl. CPC G06F 30/27; G06V 10/44

(57) ABSTRACT

A method, computer program product and system to generate higher resolution geospatial images is provided. A processor receives time sequenced spatial data images at a first resolution. A processor determines from the plurality of spatial data images physics laws applicable to the spatial data images. A processor subdivides each of the plurality of spatial data images into a plurality of small spatial region images. A processor solves each of the physics laws in each of the small spatial region images. A processor trains a neural network to apply each of the physics laws to each small spatial region image by applying a regional physics law loss function. A processor determines the most applicable regional physics law based on the difference between the small spatial region image and the image predicted for that region by the physics law. A processor generates a second higher-resolution image than the first resolution.

### BACKGROUND OF THE INVENTION

The present invention relates generally to the field of image processing, and more particularly to generating higher resolution satellite images via a physics-constrained neural network.

Satellite images are images captured at a high altitude and are typically captured by an orbiting or an atmospheric satellite (e.g., a high altitude aerial vehicle), that can capture visualization of large areas at a time. Satellite images can include images within the visible spectrum with on-board cameras or use other sensors, such as infrared image sensors, to provide up-to-date images related to global phenomenon, such as weather. Neural networks are directed graph models that represent complex relationships between inputs and outputs, that can predict an outcome when given even partial or incomplete input.

### SUMMARY

Embodiments of the present invention provide a method, computer program product and system to generate higher resolution geospatial images. A processor receives time sequenced spatial data images at a first resolution. A processor determines from the plurality of spatial data images physics laws applicable to the spatial data images. A processor subdivides each of the plurality of spatial data images into a plurality of small spatial region images. A processor solves each of the physics laws in each of the small spatial region images. A processor trains a neural network to apply each of the physics laws to each small spatial region image by applying a regional physics law loss function. A processor determines the most applicable regional physics law based on the difference between the small spatial region image and the image predicted for that region by the physics law. A processor generates a second higher-resolution image than the first resolution.

### BRIEF DESCRIPTION OF THE SEVERAL VIEWS OF THE DRAWINGS

FIG. 1 is a functional block diagram illustrating a computing environment, in accordance with an exemplary embodiment of the present invention.

FIG. 2 illustrates operational processes of an image enhancement program, on a computing device within the environment of FIG. 1, in accordance with an exemplary embodiment of the present invention.

FIG. 3 depicts an example visualization of an input satellite image and a higher resolution image generated by an image enhancement program.

FIG. 4 depicts a block diagram of components of the computing device executing an image enhancement program, in accordance with an exemplary embodiment of the present invention.

### DETAILED DESCRIPTION

The present invention may be a system, a method, and/or a computer program product at any possible technical detail level of integration. The computer program product may include a computer readable storage medium (or media) having computer readable program instructions thereon for causing a processor to carry out aspects of the present invention.

The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present invention may be assembler instructions, instruction-set-architecture (ISA) instructions, machine instructions, machine dependent instructions, microcode, firmware instructions, state-setting data, configuration data for integrated circuitry, or either source code or object code written in any combination of one or more programming languages, including an object oriented programming language such as Smalltalk, C++, or the like, and procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects of the present invention.

Aspects of the present invention are described herein with reference to flowchart illustrations and/or block diagrams of methods, apparatus (systems), and computer program products according to embodiments of the invention. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various embodiments of the present invention. In this regard, each block in the flowchart or block diagrams may represent a module, segment, or portion of instructions, which comprises one or more executable instructions for implementing the specified logical function(s). In some alternative implementations, the functions noted in the blocks may occur out of the order noted in the Figures. For example, two blocks shown in succession may, in fact, be accomplished as one step, executed concurrently, substantially concurrently, in a partially or wholly temporally overlapping manner, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

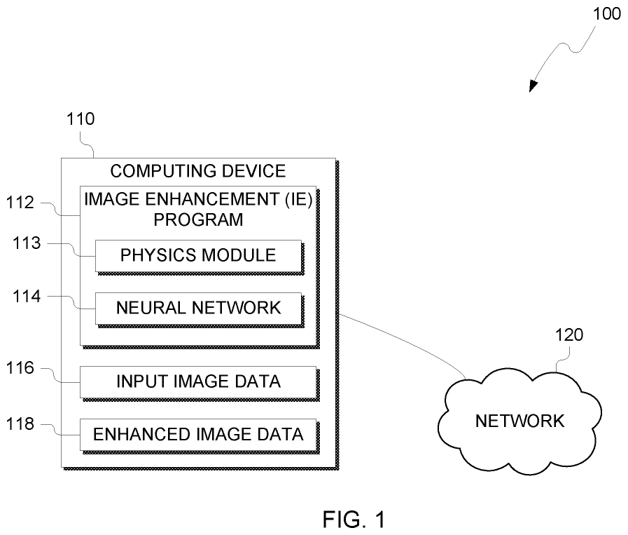

The present invention will now be described in detail with reference to the Figures. FIG. 1 is a functional block diagram illustrating computing environment, generally designated 100, in accordance with one embodiment of the present invention. Computing environment 100 includes computing device connected to network 120. Computing device 110 includes image enhancement program 112, physics module 113, neural network 114, input image data 116 and enhanced image data 118.

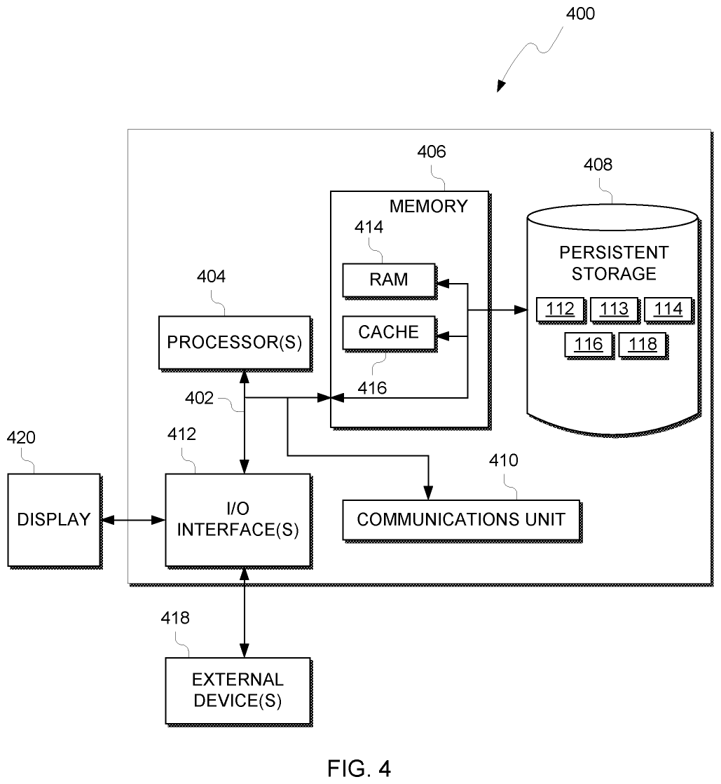

In various embodiments of the present invention, computing device 110 is a computing device that can be a standalone device, a server, a laptop computer, a tablet computer, a netbook computer, a personal computer (PC), or a desktop computer. In another embodiment, computing device 110 represents a computing system utilizing clustered computers and components to act as a single pool of seamless resources. In general, computing device 110 can be any computing device or a combination of devices with access to physics module 113, neural network 114, input image data 116 and enhanced image data 118 and is capable of executing image enhancement program 112. Computing device 110 may include internal and external hardware components, as depicted and described in further detail with respect to FIG. 4.

In this exemplary embodiment, image enhancement program 112, physics module 113, neural network 114, input image data 116 and enhanced image data 118 are stored on computing device 110. However, in other embodiments, image enhancement program 112, physics module 113, neural network 114, input image data 116 and enhanced image data 118 may be stored externally and accessed through a communication network, such as network 120. Network 120 can be, for example, a local area network (LAN), a wide area network (WAN) such as the Internet, or a combination of the two, and may include wired, wireless, fiber optic or any other connection known in the art. In general, network 120 can be any combination of connections and protocols that will support communications between computing device 110 and any other device (not shown) connected to network 120, in accordance with a desired embodiment of the present invention.

In various embodiments, image enhancement (IE) program 112 receives input image data 116 which includes various satellite images or simulations for that area. The images are stored in sequence from the times the images were captured. In some embodiments, input image data 116 may be arrange in an arbitrary sequence. Additionally, images may be captured optically via an image sensor or through a variety of other sensors, such as RADAR, gravitational field, magnetic field strength, or thermal imagery. Input image data 116 also includes a layer or other embedding in the image that conveys some physical/meteorological or other geolocated data that occurred in the area when the sequence was captured, such as, air temperature or humidity. Input image data 116 may also include non-metrological data that is geospatial, such as smoke density of a wildfire. One of ordinary skill in the art will appreciate that input image data 116 can be an arrangement of any geospatial data that adhere to one or more physics' laws, as discussed herein.

In various embodiments, IE program 112 includes physics module 113 which includes various models and equations that can model various physics/weather and other phenomenon that has been captured in input image data 116. For example, an area with a forest fire causing a smoke plume is captured in input image data 116, with geospatial data indicating smoke density in various sections of input image data 116 (e.g., smoke density per square mile). Physics module 113 includes the following model for convection-diffusion:

∂ₜC+∇*Cu=∇(K*∇C)+S [E.1]

For equation E.1, C is the concentration of the plume in the given section, S is any sources or sinks in the section, K is the diffusion coefficient for the section, and u is the velocity component of the medium (e.g., wind speed and direction).

In various embodiments, IE program 112 separates input image data 116 into a series of primary sections corresponding to parts of the captured satellite imagery. In some scenarios, each section corresponds to each pixel of geospatial data where the images may clearly resolve the physics within that particular image. While the image may be at a certain resolution, the actual physics that govern that system behaviors may have been captured at another resolution. Based on the resolution of the various meteorological or other geospatial data points in input image data 116, each measurement or pixel is separated into a primary section. For example, if a satellite image includes air temperature readings for each square kilometer in an image, then the primary sections are set to a corresponding square kilometer size to match the resolution of the geospatial data. If multiple geospatial data points are present in input image data 116, then IE program 112 sets the primary section size to the lowest resolution (e.g., smallest area per measurement) of the data points. In some scenarios, IE program 112 sets the primary sections to be a fixed size according to a grid such as latitudinal and longitudinal coordinates or it can have an arbitrary shape, like a polygon. The boundary of the regions is calculated based on the dominant physics in that area and a user defined threshold. Such example can be the identification of a hurricane or high wind conditions, where the user can define the threshold that define a wind condition. In another embodiment, the computer will determine the boundary, based on the strength of the physics. One such example, is the separation of high wind and high precipitation area during a hurricane, where the physics laws that determine the strength can be different and two area can be created based on a observations and threshold values. The two area can be separated where the boundary layer can be a combination of two physics laws that operated simultaneously (high wind and high precipitations acting at the same time) where the boundary can change in subsequent images as one physics law became dominant over the other physics law.

In various embodiments, physics module 113 includes various constraint-based models directed towards phenomenon and other observable events that can be captured by input image data 116. For example, physics module 113 may include one or more of the following physics models from the table below:

| | | | Equations of |
|---|---|---|---|
| | | | State/Constitutive |
| Physics Type | Variables | PDE expressions G[v] | Equations |
| Gas Dynamics | ρ, p, \vec{u} | ∂ₜp + div(ρ\vec{u}), | c = c(p, ρ) |
| | | ∂ₜp + \vec{u} · grad(p) + ρc²div(\vec{u}), | |
| | | ${\partial }_{t} \vec{u} + ( \vec{u} \cdot ∇ ) \vec{u} + ( \frac{1}{ρ} ) grad ( p )$ | |
| Compressible Fluid Flow | p, \vec{u} | ∂ₜp + div(ρ\vec{u}), $\begin{matrix}{\partial }_{t} \vec{u} + ( \vec{u} \cdot ∇ ) \vec{u} + \\ ( \frac{1}{ρ} ) grad ( p ) + μΔ \vec{u}\end{matrix}$ | p = p(ρ), p(ρ, S) |
| Incompressible Ideal Fluid Flow | ρ, p, \vec{u} | ∂ₜp + \vec{u} · grad(p), div(\vec{u}), ${\partial }_{t} \vec{u} + ( \vec{u} \cdot ∇ ) \vec{u} + ( \frac{1}{ρ} ) grad ( p ) ,$ | |
| | | $\begin{matrix}div ( ( \frac{1}{ρ} ) grad ( p ) ) + \\ ( grad \vec{u} ) \cdot {( grad \vec{u} )}^{t}\end{matrix}$ | |
| Electromagnetism | \vec{E}, \vec{B} | \vec{E} − c · curl \vec{B} + 4π\vec{J}, | ρ(t, \vec{x}), |
| | | div \vec{E} − 4πp, | J(t, \vec{x}), |
| | | [symbol] + c · curl \vec{E}_{,} | ρₜ + div(\vec{J}) = 0 |
| | | div \vec{B} | |
| Magnetohydrodynamics | ρ, \vec{u}, \vec{B} | ρₜ + div(ρ\vec{u}), ρ(\vec{u}ₜ + (\vec{u} · grad \vec{u}) − \vec{J}X\vec{B} + grad p − μΔ\vec{u}, [symbol] − curl(\vec{μ}X\vec{B}) + ηΔ\vec{B}, div \vec{B} | p = p(ρ), $\vec{J} = \frac{1}{{μ}_{0}} curl \vec{B}$ |
| Incompressible Magnetohydrodynamics | ρ, \vec{u}, p, \vec{B} | ρₜ + div(ρ\vec{u}), div(\vec{u}), ρ(\vec{u}ₜ + (\vec{u} · grad \vec{u}) − \vec{J}X\vec{B} + grad p, [symbol] − curl(\vec{μ}X\vec{B}) + ηΔ\vec{B}, div \vec{B}, | $\vec{J} = \frac{1}{{μ}_{0}} curl \vec{B}$ |
| | | $\begin{matrix}div ( ( \frac{1}{ρ} ) grad ( p ) ) + ( grad \vec{u} ) \cdot \\ {( grad \vec{u} )}^{t} - div ( ( \frac{1}{ρ} ) \vec{J} X \vec{B} )\end{matrix}$ | |

In the above table, “Physics Type” indicates the natural laws that may be present or impacting the information presented in input image data 116. “Variables” indicate the measured variables in each subsection. For example, when solving for “Gas Dynamics” ρ is the density of gas for a pixel in input image data 116 and p is the pressure of the gas for the pixel in input image data 116. PDE expressions are partial differential equations that must be solved for in order for the model to be satisfied. Once each expression is solved, the resultant “Variables” that produce the solution are the expected values of the physical model for the pixels or parts the super-resolved image. For example, once IE program 112 solves for the variables of the gas dynamics model for a pixel in the super-resolved image, then IE program 112 identifies an expected “density” or “pressure” measurement for the subsection's pixel. The “Equations of State/Constitutive Equations” section indicates constants and other constraints that must be satisfied for the PDE expression to be correct when solved.

In scenarios where the sequence of images of input image data 116 are not in a sequential order, IE program 112 determines the rate of change between all images in input image data 116. The amount of change from each comparison images is used to reorder the images in the right sequence. If multiple physics laws apply to a section or subsection, IE program 112 will rank sections/subsection of the images based on rate of change. In some scenarios, the rank of sections/subsections may be provided to neural network 114 as an input.

In some scenarios, the original image data sets from satellite may not be enough in size and quality to train the neural network and simulations based on the dominant physics laws can be generated using the physics laws, where the training images can be generated at arbitrary spatial and temporal resolution. In such scenarios, IE program 112 generates simulated images based on a physics simulation using physics module 113, using the simulated images as training data for neural network 114.

In various embodiments for each primary section, IE program 112 generates two or more subsections with a predicted value for each subsection. As discussed herein, based on training and application of a neural network to the geospatial data, IE program 112 generates a higher resolution image, enhanced image data 118, based on the geospatial data of input image data 116. Where the original geospatial imaging in input image data 116 is captured at a certain resolution, IE program 112 generates a higher resolution geospatial image of input image data 116, sometimes referred to as a super resolved image of input image data 116. In prior solutions, super resolution is achieved via pixel interpolation which guesses higher resolution pixels based on average values of neighboring pixels. Embodiments of the present invention provide novel techniques and systems to apply a neural network to simulate subsection pixels. By comparing the output of the neural network with constraints of various physics models determined by physics module 113, IE program 112 generates a higher resolution geospatial image of input image data 116.

In various embodiment, the network learns to harmonize physics laws at different spatial and temporal scale, like identifying and enforcing seasonal changes that may be present in the images, e.g greening of trees or losing the leaves. In another embodiment the network can detect changes in the images, like damage from a high wind where the damage can be quantified based on the area of the change.

In various embodiments, neural network 114 can be any general adversarial neural network or GANs. GANs comprise two neural networks that are “adversarial” or opposed to one another, where that outputs layers of both are compared in a loss function. In this arrangement, neural network 114 includes a trained neural network for increasing resolution in input image data 116. In this setup, neural network 114 includes two neural networks, a generator network and a discriminator network, which form the adversarial aspect of the GAN. The generator network is trained to generate higher resolution image data. Based on an image set of known satellite data and images, the generator is supervised and trained to predict super-resolved images. The discriminator network generates a loss measurement of the predictions. The discriminator network is trained to distinguish the incorrect or inconsistent predictions for super-resolved images. If the generator produces implausible or incorrect results, the discriminator penalizes the generator by increasing the loss value for the prediction. Once both the generator network and discriminator network produce a super-resolved image that minimizes the loss function, IE program 112 evaluates the super-resolved image for consistency using identified physics laws by physics module 113 that applicable to subsections of the image.

In various embodiments, neural network 114 includes a loss function that minimizes both the typical loss found in the GAN as well as a physical inconsistency metric derived from physics module 113. Based on the applicable physics laws for a subsection, IE program 112 determines a physical inconsistency metric which compares the predicted pixel of neural network to the applicable physics laws identified to the section or subsection. The physical inconsistency metric is determined by physics module 113 for each pixel by comparing the pixels physical prediction to other pixels values for the same type of prediction surrounding the candidate pixel. For example, if the super-resolved image is increasing the pixel density of smoke density, physics module 113 compares the expected density, p, for a pixel to other pixels in adjacent subsections.

For each connecting section, physics module 113 enforces energy, flux, and mass conservation between sections. For any adjacent predictions that does not maintain energy, flux, and mass conservation between sections, then physics module 113 determines the physical inconsistency metric for each pixel based on lack of conservation when comparing subsections to an overall section comprising the subpixel and any adjacent subsections for the larger overall section. In various embodiments, IE program 112 ensures that adjacent subsections respect and maintain any applicable physis laws to the adjacent subsections.

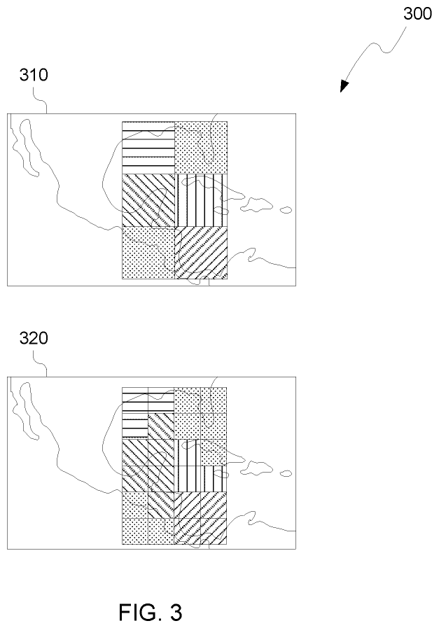

Looking at FIG. 3, FIG. 3 depicts an example visualization 300 of an input satellite image 310 and a higher resolution image 320 generated by an IE program 112 as enhanced image data 118. Input satellite image 310 depicts an example input image data 116 that includes six pixels of observed conditions in a satellite image. For example, each pixel may represent cloud density or wind speed over the given area of each pixel. As discussed herein, IE program 112 generates a higher resolution image 320 by separating each pixel in input satellite image 310 into multiple subsections. In this example, IE program 112 is performing a pixel doubling of the original input satellite image 310, where four pixels or subsections are generated in higher resolution image 320 for each pixel in input satellite image 310. For each subsection or subpixel of higher resolution image 320 relative to input satellite image 310, IE program 112 determines a pixel value for the subsections. Neural network 114, as discussed herein, generates a prediction for each subpixel based on a trained GAN network based on minimizing a loss function between a generator neural network and a discriminator neural network. In tandem, physics module 113 solves one or more constraint-based physics models to predict each subpixel. If the prediction includes some loss in conservation of energy, flux, and mass when compared to adjacent pixels, then physics module 113 generates a physical inconsistency metric for the subpixel, which is included in the loss function of neural network 114. Then IE program 112 selects the prediction from neural network 114 that minimizes the GAN's loss function, with the included physical inconsistency metric derived from physics module 113.

Returning to FIG. 1, IE program 112 generates subpixels in enhanced image data 118 based on the subpixel that minimizes the loss function of neural network 114 with the added physical inconsistency metric derived from physics module 113. Once enhanced image data 118 is initially generated, IE program 112 evaluates the subsections of enhanced image data 118 to determine any dominant or impactful physics laws that may be influencing input image data 116. Based on the physical inconsistency metric exceeding a threshold value, IE program 112 identifies each physics law applied to adjacent subsections. If the law is not applied to an adjacent subsection, IE program 112 applies the law to the adjacent subsections. Then IE program 112 repeats the above processes, reapplying the new laws for the subsections by physics module 113. If the physical inconsistency metric is lowered by expanding the effect of a physics model, then IE program 112 expands the application of the physics laws to the adjacent subsection. IE program 112 repeats these replacements until an optimal physical inconsistency metric is achieved.

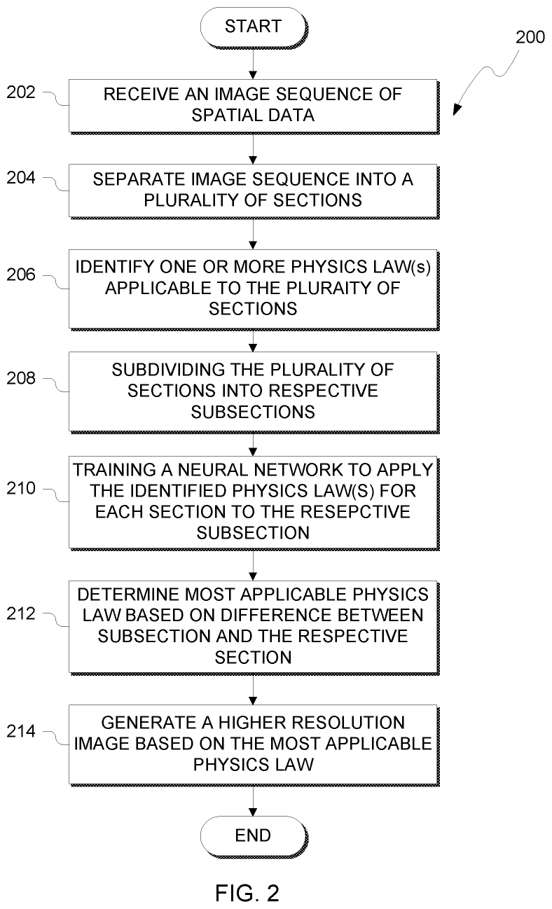

FIG. 2 illustrates operational processes, generally designated 200, of image enhancement (IE) program 112. In process 202, IE program 112 receives an image sequence of spatial data. The image sequence has captured spatial data for a given area of some period of time. In process 204, IE program 112 separates each image into sections. In some scenarios, IE program 112 creates a section for each data element or pixel of the spatial data contained in the images. In other scenarios, IE program 112 separates the image into larger sections based on the coordinates or locations of specific spatial data clusters. For example, a certain area may have cloud cover spatial data due to a cloud system passing overhead but another area of the image has little to no cloud cover spatial data, as no weather system is affecting the area. As such, IE program 112 may create larger sections for unaffected areas than per pixel basis to save on computing resources.

In process 206, IE program 112 identifies one or more physics laws applicable to each section of the sequence of images generated in process 204. As discussed herein, physics module 113 of IE program 112 includes various PDE models for different physics laws. By evaluating the various sections and the input image data 116 predicted subsections of enhanced image data 118, IE program 112 determines which PDE models correlate with data points found in sections of the input image. If a physics model does not produce output, or statistically meaningful output (i.e., the impact or output of a model is below a threshold value), then IE program 112 determines the model is not applicable to the section or subsection. If, however a physics model produced a greater result with the same data, then IE program 112 identifies that the model for the physics law is applicable.

In process 208, IE program 112 subdivides each section into two or more subsections. For example, for each pixel or data element in an image, IE program 112 may double the pixel count creating a 2×2 pixel block for each 1×1 pixel. IE program 112 may select any scaling factor since, as previously discussed, IE program 112 does not utilize any pixel interpolation as prior image enhancement solutions have utilized. In process 210, IE program 112 trains neural network 114 based on the identified applicable physics laws from process 206. In some scenarios, IE program 112 is supervised by a user while training neural network 114 with a training data set. In other scenarios, IE program 112 performs unsupervised training on neural network 114. In such scenarios where an adversarial neural network is deployed, IE program 112 may automatically retrain neural network 114 if the loss function exceeds a threshold value for a predetermined number of pixels (e.g., over half of the subpixels have minimized loss functions above a certain error rate).

In process 212, IE program 112 determines the most applicable physics law or model for each section. Based on the determined loss function the adversarial neural network 114 for each subsection, the physics law and corresponding network model that generates the smallest loss function is determined to be the most applicable. Once the most applicable law or model is determined, IE program 112 generates the pixels for the subsections based on the selected physics' law. As such, in process 214, IE program 112 generates a higher resolution image with each subsection increasing the pixel count of the input image sequence.

FIG. 4 depicts a block diagram, 400, of components of computing device 110, in accordance with an illustrative embodiment of the present invention. It should be appreciated that FIG. 4 provides only an illustration of one implementation and does not imply any limitations with regard to the environments in which different embodiments may be implemented. Many modifications to the depicted environment may be made.

Computing device 110 includes communications fabric 402, which provides communications between computer processor(s) 404, memory 406, persistent storage 408, communications unit 410, and input/output (I/O) interface(s) 412. Communications fabric 402 can be implemented with any architecture designed for passing data and/or control information between processors (such as microprocessors, communications and network processors, etc.), system memory, peripheral devices, and any other hardware components within a system. For example, communications fabric 402 can be implemented with one or more buses.

Memory 406 and persistent storage 408 are computer-readable storage media. In this embodiment, memory 406 includes random access memory (RAM) 414 and cache memory 416. In general, memory 406 can include any suitable volatile or non-volatile computer-readable storage media.

Image enhancement program 112, physics module 113, neural network 114, input image data 116 and enhanced image data 118 are stored in persistent storage 408 for execution and/or access by one or more of the respective computer processors 404 via one or more memories of memory 406. In this embodiment, persistent storage 408 includes a magnetic hard disk drive. Alternatively, or in addition to a magnetic hard disk drive, persistent storage 408 can include a solid state hard drive, a semiconductor storage device, read-only memory (ROM), erasable programmable read-only memory (EPROM), flash memory, or any other computer-readable storage media that is capable of storing program instructions or digital information.

The media used by persistent storage 408 may also be removable. For example, a removable hard drive may be used for persistent storage 408. Other examples include optical and magnetic disks, thumb drives, and smart cards that are inserted into a drive for transfer onto another computer-readable storage medium that is also part of persistent storage 408.

Communications unit 410, in these examples, provides for communications with other data processing systems or devices, including resources of network 120. In these examples, communications unit 410 includes one or more network interface cards. Communications unit 410 may provide communications through the use of either or both physical and wireless communications links. Image enhancement program 112, physics module 113, neural network 114, input image data 116 and enhanced image data 118 may be downloaded to persistent storage 408 through communications unit 410.

I/O interface(s) 412 allows for input and output of data with other devices that may be connected to computing device 110. For example, I/O interface 412 may provide a connection to external devices 418 such as a keyboard, keypad, a touch screen, and/or some other suitable input device. External devices 418 can also include portable computer-readable storage media such as, for example, thumb drives, portable optical or magnetic disks, and memory cards. Software and data used to practice embodiments of the present invention, e.g., image enhancement program 112, physics module 113, neural network 114, input image data 116 and enhanced image data 118, can be stored on such portable computer-readable storage media and can be loaded onto persistent storage 408 via I/O interface(s) 412. I/O interface(s) 412 also connect to a display 420.

Display 420 provides a mechanism to display data to a user and may be, for example, a computer monitor, or a television screen.

The programs described herein are identified based upon the application for which they are implemented in a specific embodiment of the invention. However, it should be appreciated that any particular program nomenclature herein is used merely for convenience, and thus the invention should not be limited to use solely in any specific application identified and/or implied by such nomenclature.

What is claimed is:

1. A computer-implemented method comprising:
receiving a first plurality of time sequenced spatial data images at a first resolution;
determining from one or more of the plurality of spatial data images one or more physics laws applicable to the one or more spatial data images;
subdividing each of the one or more plurality of spatial data images into a plurality of small spatial region images;
solving each of the one or more physics laws in each of the small spatial region images to determine physics law coefficients for that small spatial region image;
training a neural network to apply each of the physics laws to each small spatial region image by applying a regional physics law loss function;
determining the most applicable regional physics law based on the difference between the small spatial region image and the image predicted for that region by the physics law;
generating a second higher-resolution image than the first resolution by applying the neural network for the most applicable regional physics law to the first plurality of time sequenced images.

2. The computer-implemented method of claim 1, the computer-implemented method further comprising:
determining at least one pixel of the second higher-resolution image based on the neural network;
determining a physical inconsistency metric for the at least one pixel of the second resolution higher based on the neural network; and
applying the physical inconsistency metric to a loss function of the neural network.

3. The computer-implemented method of claim 2, wherein the neural network is an adversarial neural network.

4. The computer-implemented method of claim 2, wherein the subdivisions in the second higher-resolution image are compared to adjacent subdivisions for conservation of the applicable regional physics law.

5. The computer-implemented method of claim 4, wherein values for the adjacent subdivisions of the applicable regional physics law ensure conservation of the applicable regional physics law between the adjacent subdivisions.

6. The computer-implemented method of claim 5, wherein the neural network in penalized for determinations that do not ensure conservation of the applicable regional physics law between the adjacent subdivisions.

7. The computer-implemented method of claim 6, wherein energy, mass or flux between the adjacent subdivisions is conserved.

8. A computer program product comprising:
one or more computer-readable storage media and program instructions stored on the one or more computer-readable storage media, the program instructions comprising:
program instructions to receive a first plurality of time sequenced spatial data images at a first resolution;
program instructions to determine from one or more of the plurality of spatial data images one or more physics laws applicable to the one or more spatial data images;
program instructions to subdivide each of the one or more plurality of spatial data images into a plurality of small spatial region images;
program instructions to solve each of the one or more physics laws in each of the small spatial region images to determine physics law coefficients for that small spatial region image;
program instructions to train a neural network to apply each of the physics laws to each small spatial region image by applying a regional physics law loss function;
program instructions to determine the most applicable regional physics law based on the difference between the small spatial region image and the image predicted for that region by the physics law;
program instructions to generate a second higher-resolution image than the first resolution by applying the neural network for the most applicable regional physics law to the first plurality of time sequenced images.

9. The computer program product of claim 8, the program instructions further comprising:
program instructions to determine at least one pixel of the second higher-resolution image based on the neural network;
program instructions to determine a physical inconsistency metric for the at least one pixel of the second resolution higher based on the neural network; and
program instructions to apply the physical inconsistency metric to a loss function of the neural network.

10. The computer program product of claim 9, wherein the neural network is an adversarial neural network.

11. The computer program product of claim 9, wherein the subdivisions in the second higher-resolution image are compared to adjacent subdivisions for conservation of the applicable regional physics law.

12. The computer program product of claim 11, wherein values for the adjacent subdivisions of the applicable regional physics law ensure conservation of the applicable regional physics law between the adjacent subdivisions.

13. The computer program product of claim 12, wherein the neural network in penalized for determinations that do not ensure conservation of the applicable regional physics law between the adjacent subdivisions.

14. The computer program product of claim 13, wherein energy, mass or flux between the adjacent subdivisions is conserved.

15. A computer system comprising:
one or more computer processors;
one or more computer readable storage media; and
program instructions stored on the computer readable storage media for execution by at least one of the one or more processors, the program instructions comprising:
program instructions to receive a first plurality of time sequenced spatial data images at a first resolution;
program instructions to determine from one or more of the plurality of spatial data images one or more physics laws applicable to the one or more spatial data images;
program instructions to subdivide each of the one or more plurality of spatial data images into a plurality of small spatial region images;
program instructions to solve each of the one or more physics laws in each of the small spatial region images to determine physics law coefficients for that small spatial region image;
program instructions to train a neural network to apply each of the physics laws to each small spatial region image by applying a regional physics law loss function;
program instructions to determine the most applicable regional physics law based on the difference between the small spatial region image and the image predicted for that region by the physics law;
program instructions to generate a second higher-resolution image than the first resolution by applying the neural network for the most applicable regional physics law to the first plurality of time sequenced images.

16. The computer system of claim 15, the program instructions further comprising:
program instructions to determine at least one pixel of the second higher-resolution image based on the neural network;
program instructions to determine a physical inconsistency metric for the at least one pixel of the second resolution higher based on the neural network; and
program instructions to apply the physical inconsistency metric to a loss function of the neural network.

17. The computer system of claim 16, wherein the neural network is an adversarial neural network.

18. The computer system of claim 16, wherein the subdivisions in the second higher-resolution image are compared to adjacent subdivisions for conservation of the applicable regional physics law.

19. The computer system of claim 18, wherein values for the adjacent subdivisions of the applicable regional physics law ensure conservation of the applicable regional physics law between the adjacent subdivisions.

20. The computer system of claim 19, wherein the neural network in penalized for determinations that do not ensure conservation of the applicable regional physics law between the adjacent subdivisions.
